(19) United States
(12) Patent Application Publication
(10) Pub. No.: US 2008/0173937 A1
(43) Pub. Date: Jul. 24, 2008

(54) SEMICONDUCTOR MEMORY DEVICES INCLUDING VERTICALLY ORIENTED TRANSISTORS AND METHODS OF MANUFACTURING SUCH DEVICES

(75) Inventors: Hyun-Woo Chung, Seoul (KR); Jae-Man Yoon, Seoul (KR); Yong-Chul Oh, Suwon-si (KR); Hui-Jung Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/013,069

(22) Filed: Jan. 11, 2008

(30) Foreign Application Priority Data
Jan. 18, 2007 (KR) 10-2007-0005544

(51) Int. Cl. H01L 29/78; H01L 21/336

(52) U.S. Cl. 257/329; 438/268; 257/E29.262; 257/E21.41

(57) ABSTRACT

A semiconductor device includes a first active pattern including an upper portion and a lower portion formed on a substrate, a second active pattern formed on the first active pattern, and a gate surrounding the second active pattern. The upper portion of the first active pattern has a cross-sectional area substantially larger than that of the lower portion of the first active pattern. The first active pattern has a curved sidewall or a level sidewall. The second active pattern has a pillar structure. The gate provides a channel through the second active pattern.

### CROSS-REFERENCE TO RELATED APPLICATIONS

This application claims priority under 35 U.S.C. §119 to Korean Patent Application No. 2007-5544, filed on Jan. 18, 2007 in the Korean Intellectual Property Office (KIPO), the contents of which is incorporated herein by reference in its entirety.

### FIELD OF THE INVENTION

The present invention relates to semiconductor devices and, more particularly, to semiconductor devices that include transistors and methods of manufacturing such devices.

### BACKGROUND

Typically, the transistors that are used in semiconductor memory devices include a source region that provides charge carriers (e.g., electrons or holes), a drain region that drains the charge carriers from the source region, and a gate electrode that controls the current that flows between the source and drain regions. When the current is controlled by applying a voltage to the gate electrode of the transistor, the transistor is referred to as a field effect transistor. The transistor includes a channel between the source and drain regions. The charge carriers pass from the source region to the drain region through the channel. The transistor further includes a gate insulation layer between a substrate and the gate electrode that electrically insulates the gate electrode from the substrate. The channel and the source and drain regions may be in the substrate.

One way of increasing the integration of a semiconductor memory device is to reduce the cross-sectional area (i.e., the width) of the gate electrode. However, as the width of the gate electrode is decreased, a phenomena known as short channel effect may arise. The short channel effect may cause various problems in the transistor including increased leakage current, decreased breakdown voltages and/or a continuous increase of a current caused by a voltage applied to the drain region.

The short channel effect generally arises due to the shortened length of the channel between the source and the drain regions. To reduce the short channel effect, a transistor that has a recessed channel has been developed. This recessed channel increases the channel length between the source and drain regions. For example, Korean Patent No. 589056 discloses a gate electrode that fills a recess which has an expanded lower portion. In this Korean Patent, the gate electrode includes a first gate electrode that is formed on the substrate, and a second gate electrode that is formed in the recess having the expanded lower portion. Although the first gate electrode on the substrate has a shortened cross-sectional area, the length of the channel of the transistor may be increased because of the second gate electrode filling the recess.

Unfortunately, seams and/or voids may occur in the second gate electrode that fills the recess having the expanded lower portion. These seams and/or voids may deteriorate the electrical characteristics of the transistor. Additionally, the production yield of a semiconductor memory device that includes such transistors may be reduced.

As semiconductor memory devices approach storage capacities on the gigabit scale, the design rule for metal oxide semiconductor (MOS) transistors that is necessary to achieve such integration levels may approach or even fall below an uppermost limit of various photolithography processes. Recently, a transistor having a source region and a drain region formed perpendicularly to a substrate has been suggested. The transistor includes a channel formed perpendicular to the substrate between the source and drain regions.

FIG. 1 is a cross-sectional view illustrating such a prior art transistor that includes a channel that is perpendicular to the substrate.

As illustrated in FIG. 1, the transistor having the perpendicular channel includes a pillar active pattern 12, a fin active pattern 14, a gate 20, and a bit line 22.

The pillar active pattern 12 is formed on a substrate 10. A lower portion of the pillar active pattern 12 is partially etched to form a recess. The gate 20 includes a gate insulation layer pattern 16 and a gate electrode 18. The gate 20 is formed in the recess in the lower portion of the pillar active pattern 12. Impurities are implanted in portions of the substrate 10 adjacent to the pillar active pattern 12 so that impurity regions (not illustrated) are formed in portions of the substrate 10. The substrate 10 having the impurity regions is etched to form the fin active pattern 14 and the bit line 22. The fin active pattern 14 and the bit line 22 extend in the same direction. The fin active pattern 14 and the bit line 22 are parallel to each other. Adjacent bit lines 22 may be electrically isolated from each other, and may serve as source/drain regions of the transistor.

As the integration degree of a semiconductor memory device increases, the distance between adjacent fin active patterns 14 decreases. When the distance between adjacent fin active patterns 14 is decreased, the distance between adjacent bit lines 22 is also reduced. As the distance between adjacent bit lines 22 is reduced, mutual interference between adjacent bit lines 22 may occur and/or a parasitic capacitance between adjacent bit lines 22 may arise.

### SUMMARY

Pursuant to embodiments of the present invention, semiconductor devices are provided that include a first active pattern on a substrate. In these devices, a width of a transverse cross-section of the first active pattern is non-uniform. The devices further include a second active pattern that has a pillar structure on the first active pattern. The second active pattern includes a channel. A gate is provided on the second active pattern.

In some embodiments, the first active pattern may include a curved sidewall. A width of an upper portion of a transverse cross-section of the first active pattern may be larger than a minimum width of a lower portion of the transverse cross-section of the first active pattern. The channel may be oriented substantially perpendicular to a surface of the substrate from which the first active pattern protrudes. The gate may surround the second active pattern. The device may further include an impurity region in an upper portion of the first active pattern. The upper portion of the first active pattern may have a planar sidewall. The first active pattern may include an impurity region that extends from the upper portion of the first active pattern into an upper region of the lower portion of the first active pattern.

Pursuant to further embodiments of the present invention, methods of manufacturing a semiconductor device are provided in which a first active pattern having a transverse cross-section of non-uniform width is formed on a substrate. A second active pattern that has a pillar structure is formed on the first active pattern. A gate is formed on a sidewall of the second active pattern that defines a channel through the second active pattern.

In some embodiments the first active pattern may be formed by patterning the substrate to form a preliminary first active pattern and then isotropically etching the preliminary first active pattern to form the first active pattern. In such embodiments, the first active pattern may have a curved sidewall. Moreover, a width of an upper portion of a transverse cross-section of the first active pattern may be larger than a minimum width of a lower portion of the transverse cross-section of the first active pattern. In some embodiments, the gate may surround the sidewall of the second active pattern. In these embodiments, the channel may be oriented substantially perpendicular to a surface of the substrate from which the first active pattern protrudes. An impurity region may also be formed at the upper portion of the first active pattern.

In other embodiments, the first active pattern may be formed by patterning the substrate to form a first preliminary first active pattern. A sacrificial layer pattern is formed on an upper portion and a sidewall of the first preliminary first active pattern. The substrate is etched using the sacrificial layer pattern as an etching mask to form a second preliminary first active pattern. A sidewall of the second preliminary first active pattern is etched using the sacrificial layer pattern as an etching mask to form the first active pattern, where the upper portion of the first active pattern has a level sidewall and the lower portion of the first active pattern has a curved sidewall. In addition, an impurity region may be formed in the first active pattern that extends from the upper portion of the first active pattern into an upper region of the lower portion of the first active pattern.

Pursuant to still further embodiments of the present invention, semiconductor devices are provided that have fin active patterns that include upper portions and lower portions. The fin active patterns extend along a predetermined direction and are parallel to each other. A transverse cross-section of each of the fin active patterns has a non-uniform width. Bit lines are formed in the fin active patterns. Pillar active patterns are provided on the fin active patterns, the pillar active patterns being separated from each other by a predetermined distance. The devices further include gates that surround the pillar active patterns to form a channel through each of the pillar active patterns. Each channel is oriented substantially perpendicular to a major axis of its respective pillar active pattern.

In some embodiments, each of the fin active patterns includes a curved sidewall. The upper portion of each of the fin active patterns may have a level sidewall. The bit lines may extend from the upper portion of the first active pattern into an upper region of the lower portion of the first active pattern. The device may include impurity regions formed at upper portions of the pillar active patterns. The bit lines may be formed in at least the upper portions of the fin active patterns, and at least part of a sidewall of each bit line that faces an adjacent bit line may be curved.

Pursuant to still further embodiments of the invention, methods of manufacturing a semiconductor device are provided in which a substrate is patterned to form pillar active patterns. Impurity regions are formed at portions of the substrate adjacent to the pillar active patterns. Gates are formed on sidewalls of the pillar active patterns, where each gate surrounds the sidewall of a respective one of the pillar active patterns. Masks are formed on the pillar active patterns and the gates, where the masks extend along a predetermined direction and are parallel to each other. The substrate is etched using the masks to form bit lines and fin active patterns, where each of the bit lines has a non-planar sidewall.

In these methods, the bit lines and fin active patterns may be formed by anisotropically etching the substrate using the masks to form preliminary fin active patterns and preliminary bit lines, and then isotropically etching the preliminary fin active patterns and the preliminary bit lines to form the fin active patterns and the bit lines. Each fin active pattern may have a curved sidewall.

Pursuant to still further embodiments of the present invention, a semiconductor device is provided that includes a fin active pattern extending from an upper surface of a semiconductor substrate. The devices have a first impurity-doped region in an upper portion of the fin active pattern. The first impurity-doped region has a sidewall that is at least partly curved. A second active pattern is on an upper surface of the fin active pattern. The second active pattern includes a gate pattern on at least one side surface of the second active pattern, a second impurity-doped region in an upper portion of the second active pattern, and a channel extending between the first impurity-doped region and the second impurity-doped region such that the channel is oriented substantially perpendicular to the upper surface of the semiconductor substrate.

### BRIEF DESCRIPTION OF THE DRAWINGS

The above and other features and advantages of the present invention will become more apparent by describing in detail example embodiments thereof with reference to the accompanying drawings, in which:

FIG. 1 is a cross-sectional view illustrating a conventional transistor.

FIG. 2 is a cross-sectional view illustrating a semiconductor device in accordance with example embodiments of the present invention.

FIG. 2A is a cross-sectional view with labels identifying the upper and lower portions and the central and peripheral portions of a fin active pattern in the semiconductor device in accordance with the embodiment of the present invention depicted in FIG. 2.

FIG. 3 is a cross-sectional view illustrating a semiconductor device in accordance with further embodiments of the present invention.

FIGS. 4 and 5 are a cross-sectional and a perspective views, respectively, illustrating a semiconductor device in accordance with embodiments of the present invention.

FIGS. 6 and 7 are a cross-sectional and a perspective views, respectively, illustrating a semiconductor device in accordance with embodiments of the present invention.

FIGS. 8 to 23 are cross-sectional and perspective views illustrating methods of manufacturing semiconductor devices in accordance with embodiments of the present invention.

FIGS. 24 to 31 are cross-sectional and perspective views illustrating methods of manufacturing semiconductor devices in accordance with further embodiments of the present invention.

### DETAILED DESCRIPTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

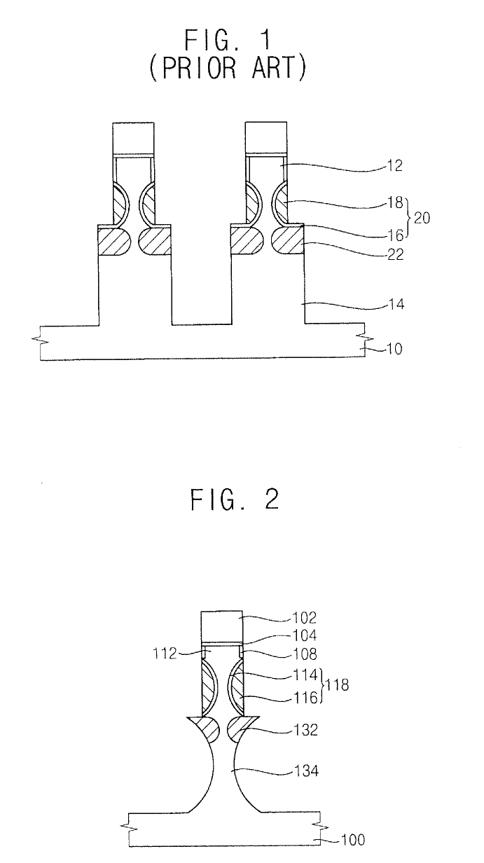

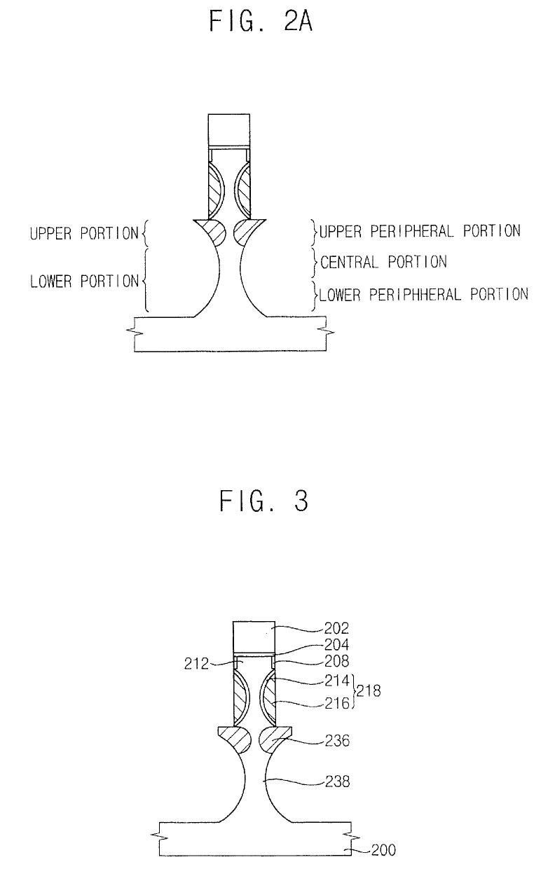

FIG. 2 is a cross-sectional view illustrating a semiconductor device in accordance with some embodiments of the present invention.

Referring to FIG. 2, the semiconductor device includes a first active pattern 134 on a substrate 100, a second active pattern 112 on the first active pattern 134, and a gate 118 that surrounds (i.e., encloses at least the side sections) the second active pattern 112. The semiconductor device further includes a first impurity region 132 formed at an upper portion of the first active pattern 134, and a second impurity region (not illustrated) formed at an upper portion of the second active pattern 112. In FIG. 2, reference numerals of “102”, “104” and “108” indicate a mask, a pad oxide layer pattern and an etch stop layer, respectively.

The substrate 100 may comprise, for example, a single crystalline silicon substrate, a single crystalline germanium substrate, a silicon-on-insulator (SOI) substrate, a germanium-on-insulator (GOI) substrate, etc.

The first active pattern 134 is on the substrate 100, and may be formed by selectively etching away upper portions of the substrate 100. Thus, the first active pattern 134 may comprise, for example, a material that is substantially the same as the material included in the substrate 100.

The first active pattern 134 may extend in a first direction (in FIG. 2, the first direction extends into the page). As illustrated in, for example, FIG. 2A, the first active pattern 134 may include an upper portion and a lower portion. As illustrated in both FIGS. 2 and 2A, a width of the upper portion of the transverse cross-section of the first active pattern 134 (which, in this case is a variable width) may be substantially larger than a width of the lower portion of the transverse cross-section of the first active pattern 134. As is also illustrated in FIGS. 2 and 2A, the first active pattern 134 may have a rounded/curved sidewall that has, for example, a predetermined curvature. Herein, the transverse cross-section refers to a cross-section taken across the length of the pattern such as, for example, the cross-sections of FIGS. 2 and 2A. Thus, for example, FIGS. 2 and 2A depict transverse cross-sections.

As is also illustrated in FIG. 2A, the first active pattern 134 may also be considered to have a central portion that is surrounded by upper and lower peripheral portions. A width of the upper peripheral portion of the transverse cross-section of the first active pattern 134 (which, in this case is a variable width) may be substantially larger than a width of the central portion of the transverse cross-section of the first active pattern 134.

Referring again to FIG. 2, a first impurity region 132 is formed at the upper portion of the first active pattern 134. Mutual interference between first impurity region 132 and a corresponding first impurity region of an adjacent transistor may be reduced by use of first active patterns such as first active pattern 134 that are formed in accordance with embodiments of the present invention.

The first impurity region 132 may include impurity elements from Group III or Group V of the Periodic Table of Elements. These elements may be used alone or in a mixture thereof. The first impurity region 132 may serve together with the second impurity region (not illustrated) as the source/drain regions of the transistor. The second active pattern 112 is on the first active pattern 134. The second active pattern 112 may have a pillar structure. Herein, by “pillar structure” it is meant that the second active pattern has an elongated, vertically-oriented (with respect to the major surface of the underlying substrate 100) structure. The pillar-shaped active patterns discussed herein can have a variety of longitudinal cross-sectional profiles (i.e., when the cross section is taken parallel to the major surface of the underlying substrate). For example, the longitudinal cross-sections may be circular, square, rectangular, polygonal, elliptical, etc.

In example embodiments of the present invention, the second active pattern 112 may include an upper portion, a central portion and a lower portion. The central portion of the second active pattern 112 may have a cross-sectional area (and/or a width) that is substantially smaller than the cross-sectional areas (and/or the widths) of the upper and the lower portions of the second active pattern 112. The central portion of the second active pattern 112 may have a curved sidewall. For example, a recess may be formed on the sidewall of the central portion of second active pattern 112.

In further embodiments of the present invention, the second active pattern 112 may include an upper portion, a central portion and a lower portion. The upper and the lower portions of the second active pattern 112 may have level (i.e., planar) sidewalls. The upper portion may have a cross-sectional area that is substantially larger than the cross-sectional area of the lower portion. A step may be formed on a sidewall of the second active pattern 112.

In still further embodiments of the present invention, the second active pattern 112 may include an upper portion and a lower portion. The upper portion may have a cross-sectional area that is substantially the same as the cross-sectional area of the lower portion.

The gate 118 is formed at the central portion of the second active pattern 112. The gate 118 may surround the central portion of the second active pattern 112. For example, the gate 118 may fill a recess or a step in the central portion of the second active pattern 112. The gate 118 includes a gate isolation layer 114 and a gate electrode 116.

The gate insulation layer 114 may include an oxide or a metal compound. For example, the gate insulation layer 114 may include silicon oxide (SiOx), hafnium oxide (HfOₓ), zirconium oxide (ZrOₓ), aluminum oxide (AlOₓ), tantalum oxide (TaOₓ), etc.

The gate electrode 116 may include polysilicon doped with impurities, a metal and/or a metal compound. For example, the gate electrode 116 may include tungsten (W), tungsten nitride (WNₓ), tungsten silicide (WSiₓ), titanium (Ti), titanium nitride (TiNₓ), titanium silicide (TiSiₓ), aluminum (Al), aluminum nitride (AlNₓ), tantalum (Ta), tantalum nitride (TaNₓ), tantalum silicide (TaSiₓ), cobalt silicide (CoSiₓ), etc.

In one example embodiment of the present invention, when the second active pattern 112 has the recess, the gate insulation layer 114 and the gate electrode 116 may fill the recess to surround the central portion of the second active pattern 112.

In another example embodiment of the present invention, when the second active pattern 112 includes a step portion, the gate insulation layer 114 and the gate electrode 116 may fill the step portion to surround the central portion of the second active pattern 112.

In still another example embodiment of the present invention, the gate 118 may be formed at the lower portion of the second active pattern 112 to surround the lower portion of the second active pattern 112 when the upper portion of the second active pattern 112 has a cross-sectional area that is substantially the same as the cross-sectional area of the lower portion of the second active pattern 112.

The second impurity region is formed on a surface of the second active pattern 112. The second impurity region may include impurities that are substantially the same as or similar to the impurities in the first impurity region 132.

According to example embodiments of the present invention, the transistor including the gate 118, the first impurity region 132 and the second impurity region is provided on the substrate 100 having the first active pattern 134 and the second active pattern 112. The gate 118 may be on the sidewall the second active pattern 112. In some embodiments, the gate 118 may surround the central portion of the second active pattern 112. The first impurity region 132 and the second impurity region may be formed at the upper portions of the first and the second active patterns 134 and 112 adjacent to the gate 118, respectively. Therefore, a transistor having a channel that is substantially perpendicular to the substrate 100 may be provided in the second active pattern 112.

In the above-described embodiments, mutual interference between adjacent first impurity regions 132 may be reduced because the lower portion (or the central portion) of the first active pattern 134 may have a cross-sectional area (and/or a width) that is substantially smaller than the cross-sectional area (and/or the width) of the upper portion (or the peripheral portion) of the first active pattern 134.

FIG. 3 is a cross-sectional view illustrating a semiconductor device in accordance with further embodiments of the present invention.

As illustrated in FIG. 3, the semiconductor device includes a first active pattern 238 that is formed on a substrate 200, a second active pattern 212 that is formed on the first active pattern 238, and a gate 218 that surrounds the second active pattern 212. The semiconductor device may further include a first impurity region 236 that is formed at an upper portion of the first active pattern 238, and a second impurity region (not illustrated) that is formed at an upper portion of the second active pattern 212. In FIG. 3, reference numerals “202”, “204”, “208”, “214” and “216” denote a mask, a pad oxide layer pattern, an etch stop layer, a gate insulation layer and a gate electrode, respectively.

The first active pattern 238 is formed on the substrate 200. In example embodiments, the first active pattern 238 may comprise a material that is substantially the same as the material included in the substrate 200.

The first active pattern 238 may include an upper portion and a lower portion. The upper portion of the first active pattern 238 may have a level (i.e., planar) sidewall. In some embodiments, the sidewall may comprise a vertical sidewall that lies in a plane that intersects the plane defined by a top surface of the substrate 200 at a right angle. A central portion of the first active pattern 238 may have a cross-sectional area (and/or a width) that is substantially smaller than the cross-sectional area (and/or the width) of a peripheral portion of the first active pattern 238. The central portion of the first active pattern 238 may have a curved sidewall.

The first impurity region 236 is formed at the upper portion of the first active pattern 238. In example embodiments, the first impurity region 236 may extend from the upper portion of the first active pattern 238 to an upper region of the lower portion of the first active pattern 238.

Mutual interference between adjacent first impurity regions 236 may be decreased as the cross-sectional area of the central portion of the first active pattern 238 is substantially smaller than the cross-sectional area of the upper and the lower peripheral portions of the first active pattern 238.

Detailed descriptions regarding the second active pattern 212, the gate 218 and the second impurity region will be omitted because these elements are substantially similar to the corresponding elements of the semiconductor device described with reference to FIG. 2.

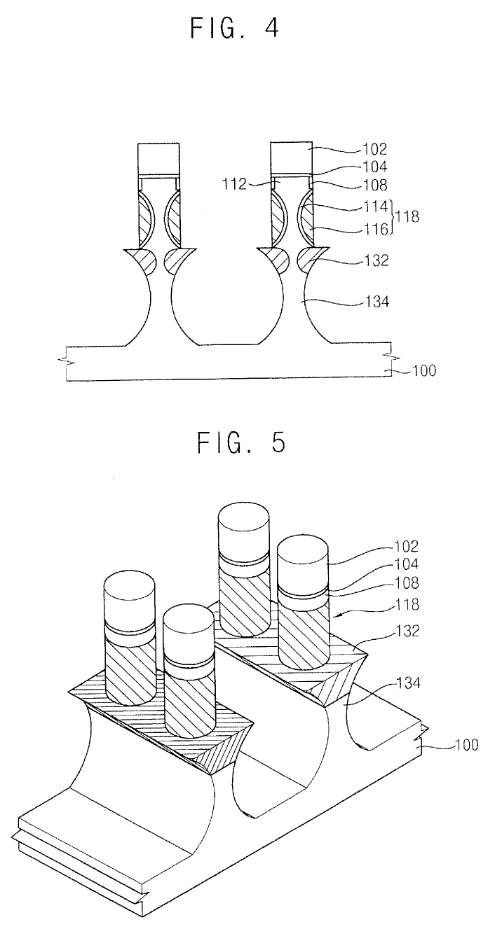

FIGS. 4 and 5 are cross-sectional and perspective views, respectively, illustrating a small portion of an array of cells in a semiconductor device in accordance with example embodiments of the present invention.

Referring to FIGS. 4 and 5, the array of the cells in the semiconductor device includes fin active patterns 134 on a substrate 100, pillar active patterns 112 on the fin active patterns 134, and gates 118 surrounding sidewalls of the pillar active patterns 112. The array of cells further includes bit lines 132 formed on the fin active patterns 134, and impurity regions (not illustrated) formed on the pillar active patterns 112.

The substrate 100 may comprise a single crystalline silicon substrate, a single crystalline germanium substrate, an SOI substrate, a GOI substrate, etc.

Each of the fin active patterns 134 formed on the substrate 100 may extend along a first direction. The fin active patterns 134 may be parallel to each other and may be separated from each other by a predetermined distance.

In some embodiments of the present invention, each fin active pattern 134 may include an upper portion and a lower portion. The upper portion may have a cross-sectional area (and/or a width) that is substantially larger than the cross-sectional area (and/or the width) of the lower portion. The fin active pattern 134 may have a curved sidewall. The curvature of the sidewall of the fin active pattern 134 may be predetermined.

In other example embodiments of the present invention, each fin active pattern 134 may include a central portion and at least one peripheral portion. The central portion of the fin active pattern 134 may have a cross-sectional area (and/or a width) that is substantially smaller than the cross-sectional area (and/or the width) of the peripheral portion. The fin active pattern 134 may have a curved sidewall.

The bit lines 132 are formed on respective ones of the fin active patterns 134. Each of the bit lines 132 may extend along a first direction that is substantially the same as the direction along which the fin active patterns 134 extend.

The bit lines 132 may include impurities. The impurities in the bit lines 132 may include elements in Group III or Group V of the Periodic Table of Elements. These may be used alone or in a mixture thereof. The bit lines 132 may serve as source/drain regions.

A distance between adjacent bit lines 132 on the fin active patterns 134 may increase because the lower portions (or the central portions) of the fin active patterns 134 may have cross-sectional areas (and/or widths) that are substantially smaller than the cross-sectional areas (and/or thewidths) of the upper portions (or the peripheral portions) of the fin active patterns 134. Thus, mutual interference between adjacent bit lines 132 and/or a parasitic capacitance in the array of the cells in the semiconductor device may be reduced.

The pillar active patterns 112 are formed on the fin active patterns 134. The pillar active patterns 112 may be separated from each other by a predetermined distance. Each of the pillar active patterns 112 may be arranged along a second direction that is substantially perpendicular to the first direction.

In some embodiments of the present invention, each of the pillar active patterns 112 may include an upper portion and a lower portion. The upper portion may have a level sidewall. The lower portion may be divided into a central portion and a peripheral portion. The central portion of the pillar active pattern 112 may have a cross-sectional area that is substantially smaller than the cross-sectional area of the peripheral portion. The lower portion of the pillar active pattern 112 may have a curved sidewall. The sidewall of the pillar active pattern 112 may have a recess.

In other embodiments of the present invention, each of the pillar active patterns 112 may include an upper portion and a lower portion. The upper and the lower portions may each have level sidewalls. The upper portion may have a cross-sectional area (and/or a width) that is substantially larger than the cross-sectional area (and/or the width) of the lower portion, so that a sidewall of the pillar active pattern 112 may have a step.

In still other embodiments of the present invention, each of the pillar active patterns 112 may include an upper portion and a lower portion. The upper portion may have a cross-sectional area (and/or a width) that is substantially the same as the cross-sectional area (and/or the width) of the lower portion.

The gates 118 include gate insulation layer patterns 114 and gate electrodes 116. The gate insulation layer patterns 114 may include oxides or metal compounds. For example, the gate insulation layer patterns 114 may include silicon oxide (SiOₓ), hafnium oxide (HfOₓ), zirconium oxide (ZrOₓ), aluminum oxide (AlOₓ), tantalum oxide (TaOₓ), etc.

The gate electrodes 116 may include polysilicon doped with impurities, metals or metal compounds. For example, the gate electrodes 116 may include tungsten (W), tungsten nitride (WNₓ), tungsten silicide (WSiₓ), titanium (Ti), titanium nitride (TiNₓ), titanium silicide (TiSiₓ), aluminum (Al), aluminum nitride (AlNₓ), tantalum (Ta), tantalum nitride (TaNₓ), tantalum silicide (TaSiₓ), cobalt silicide (CoSiₓ), etc.

In one example embodiment of the present invention, the sidewall of the pillar active pattern 112 may be recessed. Each of the gate insulation layer patterns 114 and the gate electrodes 116 may be formed on the lower portion of each of the pillar active patterns 112 to fill the respective recesses. Each gate 118 may surround the lower portion of a respective one of the pillar active patterns 112. A depth of the recess may be substantially the same as a thickness of the gate 118. Upper faces of the gates 118 and sidewalls of the upper portions of the pillar active patterns 112 may be in substantially the same plane.

In another example embodiment of the present invention, the sidewall of the pillar active pattern 112 may have a step. Each of the gate insulation layer patterns 114 and the gate electrodes 116 may be formed on the lower portion of the pillar active patterns 112 to fill the step. The gates 118 may surround the central portions of the pillar active patterns 112.

In still other embodiments of the present invention, the upper portion of the pillar active patterns 112 may have a cross-sectional area (and/or a width) that is substantially the same as the cross-sectional area (and/or the width) of the lower portion of the pillar active patterns 112. Each of the gate insulation layer patterns 114 and the gate electrodes 116 may be formed on the lower portion of the pillar active patterns 112. The gates 118 may surround the lower portions of the pillar active patterns 112, respectively.

Adjacent gate electrodes 116 may be electrically connected to word lines (not illustrated). Each of the word lines may extend along a second direction. The second direction may be substantially perpendicular to the first direction. In example embodiments, when the cross-sectional area of the upper portion of the pillar active pattern 112 is substantially the same as the cross-sectional area of the lower portion of the pillar active pattern 112, the word line may surround the lower portion or the central portion of the pillar active pattern 112. Here, the gate electrodes 116 may not be positioned on the gate insulation layer patterns 114.

The impurity regions (not illustrated) are formed in the pillar active patterns 112. Impurities of the impurity regions may include a material substantially the same as that in the bit lines 132.

The impurity regions and the bit lines 132 may serve as source/drain regions of transistors. For example, when the bit lines 132 serve as the source regions, the impurity regions may serve as the drain regions.

According to some embodiments of the present invention, transistors including the pillar active patterns 112, the gates 118 surrounding the lower portions of the pillar active patterns 112, the bit lines 132, and the impurity regions may be provided on the substrate 100. Therefore, channels substantially perpendicular to the substrate 100 may be provided in the pillar active patterns 112. In FIGS. 4 and 5, reference numerals of “102”, “104” and “108” indicate masks, pad oxide layer patterns and etch stop layers, respectively.

Mutual interference between adjacent bit lines 132 may be reduced because the lower portions (or central portions) of the fin active patterns 134 may have cross-sectional areas (and/or widths) that are substantially smaller than the cross-sectional areas (and/or the widths) of the upper portions (or peripheral portions) of the fin active patterns 134.

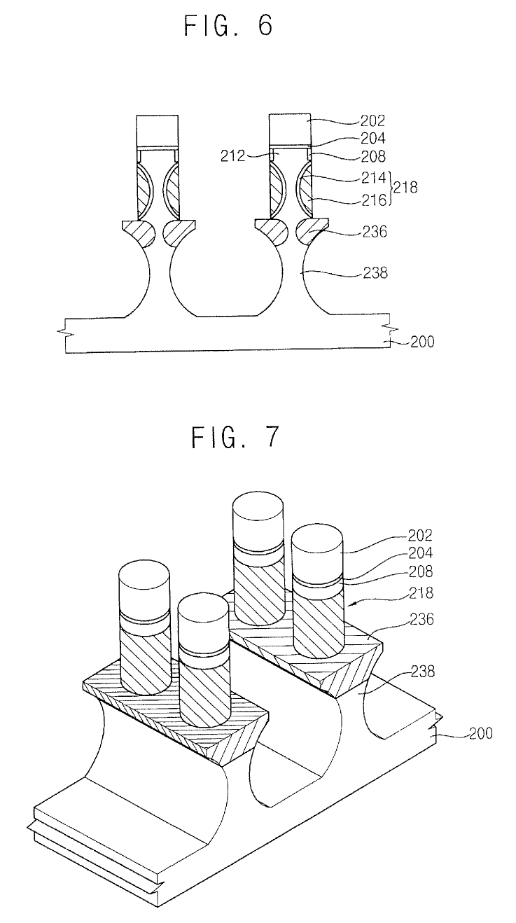

FIGS. 6 and 7 are cross-sectional and perspective views, respectively, illustrating a small portion of an array of cells in a semiconductor device in accordance with example embodiments of the present invention.

Referring to FIGS. 6 and 7, the array of the cells in the semiconductor device includes fin active patterns 238 on a substrate 200, pillar active patterns 212 on the fin active patterns 238, and gates 218 surrounding sidewalls of the pillar active patterns 212. The array of the cells in the semiconductor device further includes bit lines 236 on the fin active patterns 238, and impurity regions (not illustrated) on the pillar active patterns 212.

In some embodiments, the fin active patterns 238 may extend along a first direction on the substrate 200. The fin active patterns 238 may be parallel to each other and may be spaced apart from each other by a predetermined distance.

Each fin active pattern 238 may include an upper portion and a lower portion. The upper portions of the fin active patterns 238 may have level sidewalls. Central portions of the fin active patterns 238 may have cross-sectional areas (and/or widths) that are substantially smaller than the cross-sectional areas (and/or the widths) of peripheral portions of the fin active patterns 238. In example embodiments, the lower portions of the fin active patterns 238 may have curved sidewalls.

The bit lines 236 are on the fin active patterns 238. In some embodiments, the bit lines 236 may be positioned in first sidewalls and portions of second sidewalls of the fin active patterns 238. Each of the bit lines 236 may extend along the first direction (i.e., in substantially the same direction as the direction of the fin active patterns 238).

The bit lines 236 may include impurities. The bit lines 236 may serve as source/drain regions of the transistors. The impurities in the bit lines 236 may include elements in Group III or Group V of the Periodic Table of Elements. These impurities may be used alone or in a mixture thereof.

The distance between adjacent bit lines 236 on the fin active patterns 238 may increase because the lower portions (or the central portions) of the fin active patterns 238 may have cross-sectional areas (and/or widths) that are substantially smaller than the cross-sectional areas (and/or the widths) of the upper portions (or the peripheral portions).

Further, a mutual interference between adjacent bit lines 236 may be reduced, as may a parasitic capacitance in the array of the cells of the semiconductor device. Moreover, each of the bit lines 236 may have a substantially lower resistance because each of the bit lines 236 is formed on the upper portion of the fin active pattern 238 having the level sidewall.

Detailed descriptions of the pillar active patterns 212, the gates 218 and the impurity regions will be omitted because these elements are substantially similar to those of the semiconductor device described above with reference to FIGS. 4 and 5. In FIGS. 6 and 7, reference numerals “202”, “204”, “208”, “214” and “216” denote masks, pad oxide layer patterns, etch stop layer patterns, gate insulation layer patterns and gate electrodes, respectively.

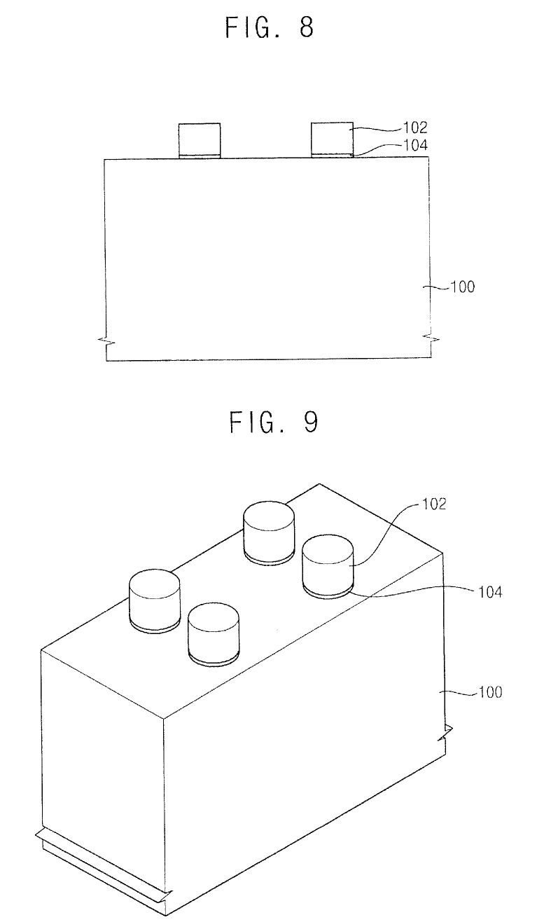

FIGS. 8 to 23 are views illustrating methods of manufacturing semiconductor devices in accordance with example embodiments of the present invention. FIGS. 8, 10, 12, 14, 16, 18, 20 and 22 are cross-sectional views, while FIGS. 9, 11, 13, 15, 17, 19, 21 and 23 are perspective views.

Referring to FIGS. 8 and 9, a pad oxide layer (not illustrated) and masks 102 are formed on a substrate 100.

The substrate 100 may include a single crystalline silicon substrate, a single crystalline germanium substrate, a SOI substrate, a GOI substrate, etc. The pad oxide layer may be formed by a thermal oxidation process or a chemical vapor deposition (CVD) process. The pad oxide layer may reduce a stress between the substrate 100 and the masks 102. The masks 102 may be formed using, for example, nitride such as silicon nitride.

In some embodiments of the present invention, a first mask layer may be formed on the pad oxide layer, and then photoresist patterns (not illustrated) may be formed on the first mask layer. An organic anti-reflection layer may be formed between the first mask layer and the photoresist patterns. The organic anti-reflection layer may reduce diffuse reflections during a photolithography process. The organic anti-reflection layer and the first mask layer may be etched using photoresist patterns as etching masks to form organic anti-reflection layer patterns and the masks 102. After forming the organic anti-reflection layer patterns and the masks 102, the organic anti-reflection layer patterns and the photoresist patterns may be removed from the masks 102 by an ashing process and/or a stripping process.

The pad oxide layer is etched using the masks 102 as etching masks to form pad oxide layer patterns 104 on the substrate 100.

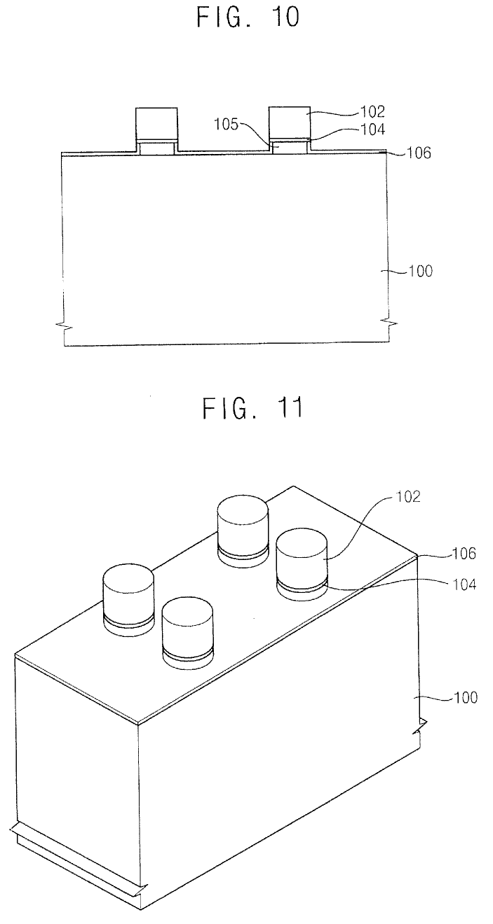

Referring to FIGS. 10 and 11, the substrate 100 is partially etched using the masks 102 and the pad oxide patterns 104 as etching masks to form first preliminary pillar active patterns 105. Each of the first preliminary pillar active patterns 105 may have a first height.

In some embodiments of the present invention, the etching process may include an anisotropic etching process so that the first preliminary pillar active patterns 105 may have level sidewalls.

An etch stop layer 106 is conformally formed on the first preliminary pillar active patterns 105 and the substrate 100. The etch stop layer 106 may be formed using an oxide, a nitride, an oxynitride, etc. The etch stop layer 106 may be a single layer structure or a multi-layer structure. The etch stop layer 106 may prevent the sidewalls of the first preliminary pillar active patterns 105 from being etched in subsequent etching processes.

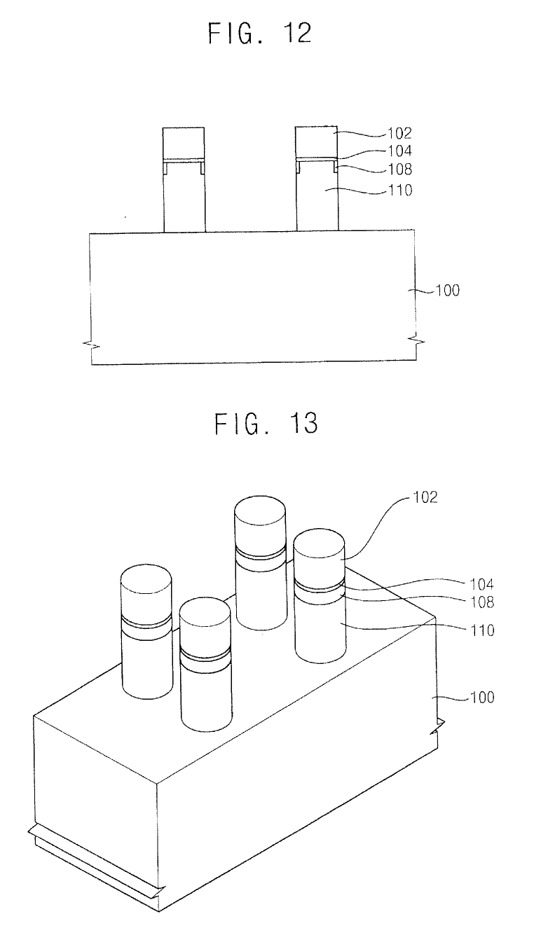

Referring to FIGS. 12 and 13, the etch stop layer 106 is etched using the masks 102 as etching masks to form etch stop layer patterns 108 on the sidewalls of the first preliminary pillar active patterns 105. In some embodiments, the etching process may include an isotropic etching process.

Portions of the substrate 100 adjacent to the first preliminary pillar active patterns 105 and the etch stop layer patterns 108 are partially etched by an etching process to form second preliminary pillar active patterns 110. In some example embodiments, the etching process may include an isotropic etching process.

Each of the second preliminary pillar active patterns 110 may have a second height that is substantially higher than the first height. The second preliminary pillar active patterns 110 may have level (i.e., planar) sidewalls.

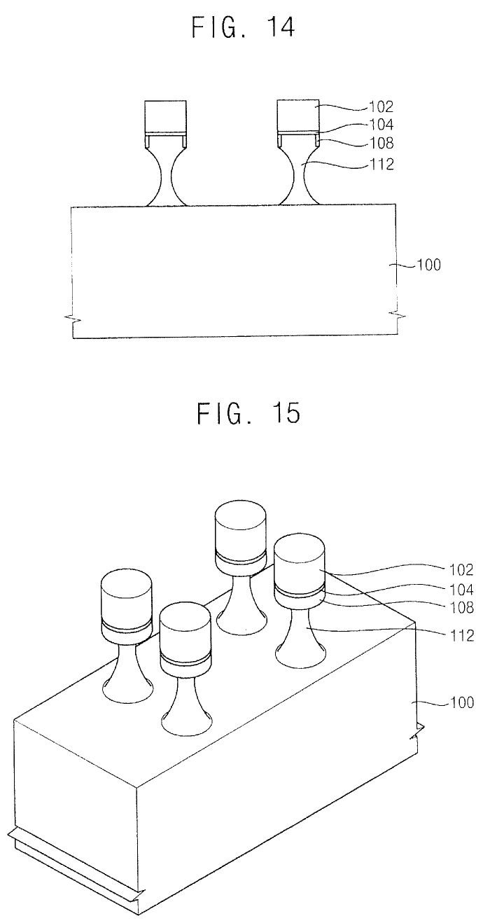

Referring to FIGS. 14 and 15, the second preliminary pillar active patterns 110 are etched using the masks 102 and the etch stop layer patterns 108 as etching masks to form pillar active patterns 112. In some embodiments, the etching process may include an isotropic etching process.

Each of the pillar active patterns 112 may have a third height that is substantially the same as the second height. The pillar active patterns 112 may include upper portions that have level sidewalls and lower portions that are recessed after the isotropic etching process.

In the isotropic etching process, the lower portion of each pillar active pattern 112 may be partially etched whereas the upper portion of each pillar active pattern 112 may remain substantially unetched because the etch stop layer patterns 108 may protect the upper portion of the pillar active patterns 112 during the etching process. Therefore, the upper portion of each pillar active pattern 112 may have a cross-sectional area (and/or a width) that is substantially larger than the cross-sectional area (and/or the width) of the lower portion of the pillar active pattern 112. In example embodiments, the sidewalls of the pillar active patterns 112 may be recessed.

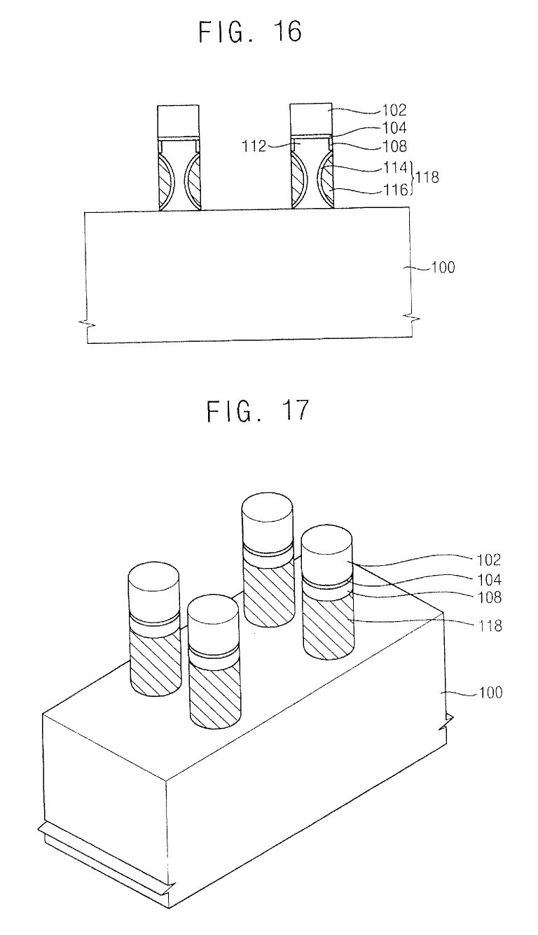

Referring to FIGS. 16 and 17, gates 118 are formed on the lower portions of each pillar active pattern 112. Each gate 118 may surround the lower portion of a respective one of the pillar active patterns 112.

In some embodiments of the present invention, a thermal oxidation process may be performed on the substrate 100 having the pillar active patterns 112 and the masks 102 to form a thermal oxide layer (not illustrated). The thermal oxide layer may be thin. Portions of the thermal oxidation layer that are formed in the recesses may serve as gate insulation layer patterns 114. Other portions of the thermal oxidation layer formed on the substrate 100 may prevent the substrate 100 from being damaged in a subsequent ion implantation process.

A conductive layer (not illustrated) is formed on the substrate 100 having the thermal oxide layer to cover the pillar active patterns 112. The conductive layer may be formed using polysilicon doped with impurities, a metal or a metal compound. For example, the conductive layer may be formed using tungsten (W), tungsten nitride (WNₓ), tungsten silicide (WSiₓ), titanium (Ti), titanium nitride (TiNₓ), titanium silicide (TiSiₓ), aluminum (Al), aluminum nitride (AlNₓ), tantalum (Ta), tantalum nitride (TaNₓ), tantalum silicide (TaSiₓ), cobalt silicide (CoSiₓ), etc. The conductive layer may be partially etched to expose the upper faces of the pillar active patterns 112.

The conductive layer is etched using the masks 102 as etching masks to form gate electrodes 116 that fill the recesses in the lower portions of the pillar active patterns 112. Therefore, gates 118 that include the gate insulation layer patterns 114 and the gate electrodes 116 may be formed on the lower portions of the pillar active patterns 112. The upper faces of the gate electrodes 116 and the sidewalls of the upper portions of the pillar active patterns 112 may be positioned in the same plane.

In some embodiments of the present invention, adjacent gate electrodes 116 may be electrically connected to word lines (not illustrated). Each of the word lines may extend along the first direction. The first direction may be different from the direction in which the fin active patterns 134 extend (see FIGS. 4 and 5).

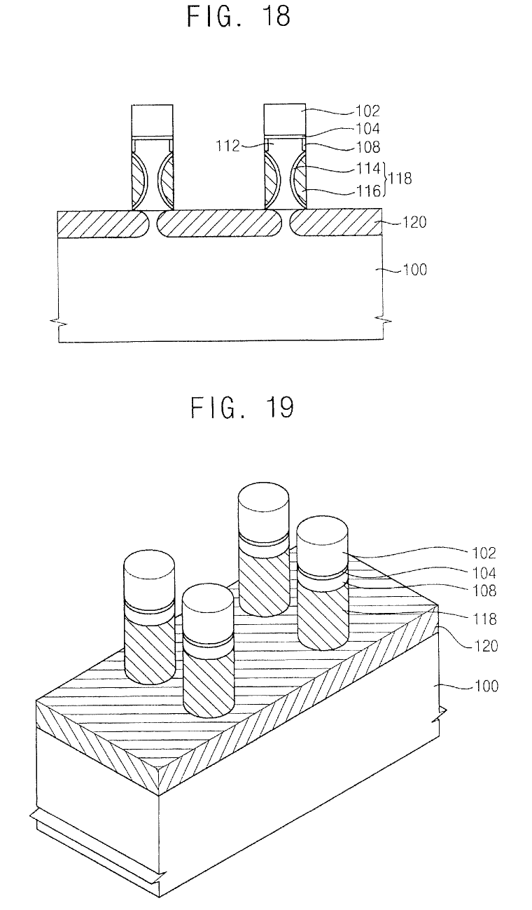

Referring to FIGS. 18 and 19, impurities are implanted into portions of the substrate 100 adjacent to the pillar active patterns 112 and the masks 102 to form a preliminary first impurity region 120. The implanted impurities may include elements in Group III or Group V of the Periodic Table of Elements. These may be used alone or in a mixture thereof.

After the ion implantation process, a thermal diffusion process may be performed on the substrate 100 to diffuse the impurities beneath the pillar active patterns 112. Adjacent preliminary first impurity regions 120 may contact each other.

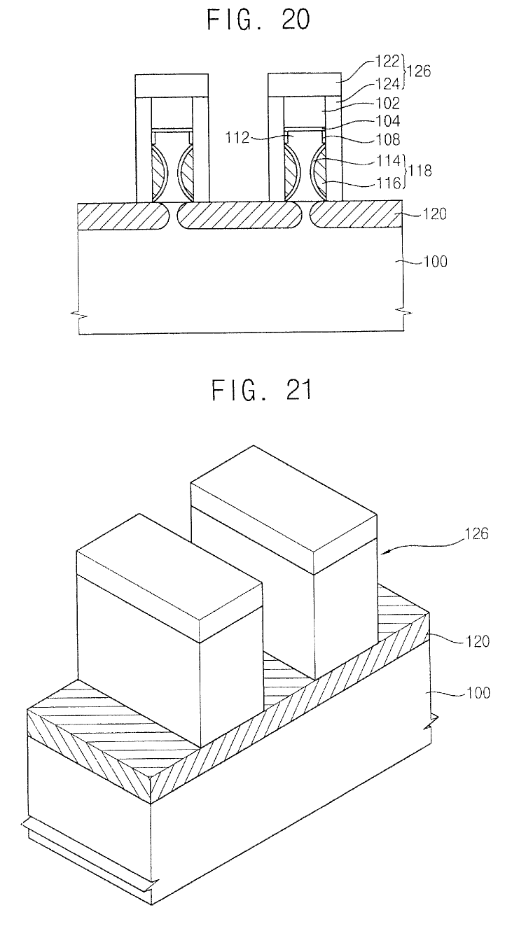

As illustrated in FIGS. 20 and 21, sacrificial layer patterns 126 may be formed on the sidewalls of the pillar active patterns 112 and the upper faces of the masks 102. Each of the sacrificial layer patterns 126 may extend along the second direction which is different from the first direction. In some embodiments, the second direction may be substantially perpendicular to the first direction

In some embodiments of the present invention, the sacrificial layer patterns 126 may be formed as follows. A first sacrificial layer (not illustrated) may be formed on the masks 102 to cover the pillar active patterns 112. The first sacrificial layer may be formed using a material that has etching selectivity relative to the substrate 100. For example, the first sacrificial layer may be formed using an oxide such as borophosphosililcate glass (BPSG), tonen silazene (TOSZ), undoped silicate glass (USG), spin-on glass (SOG), flowable oxide (FOX), tetraethylorthosilicate (TEOS), high density plasma-CVD (HDP-CVD) oxide, etc.

The first sacrificial layer may be planarized by a planarization process. For example, the planarization process may include a chemical mechanical polishing (CMP) process and/or an etch-back process.

A second sacrificial layer (not illustrated) may be formed on the first sacrificial layer having the planarized surface. The second sacrificial layer may be formed using an oxide such as TEOS.

An organic anti-reflection layer (not illustrated) and photoresist patterns (not illustrated) may be formed on the second sacrificial layer. The organic anti-reflection layer may include amorphous carbon and/or silicon oxynitride. Each of the photoresist patterns may have a cross-sectional area that is substantially wider than the cross-sectional area of the pillar active patterns 112. The photoresist patterns may have bar structures extending along the second direction and may be parallel to each other. The photoresist patterns may be separated from each other by a predetermined distance.

The organic anti-reflection layer and the second sacrificial layer may be etched using the photoresist patterns as etching masks to form organic anti-reflection layer patterns (not illustrated) and second sacrificial layer patterns 122. In some embodiments, the etching process may include an anisotropic etching process.

The first sacrificial layer may be continuously etched by an etching process to form first sacrificial layer patterns 124 on the sidewalls of the pillar active patterns 112. In some example embodiments, the etching process may include an anisotropic etching process.

Each of the first sacrificial layer patterns 124 may extend along the second direction. The first sacrificial layer patterns 124 may be parallel to each other. The sacrificial layer patterns 126 include the first sacrificial layer patterns 124 and the second sacrificial layer patterns 122. After forming the sacrificial layer patterns 126, the photoresist patterns and the organic anti-reflection layer patterns may be removed by an ashing process and/or a stripping process.

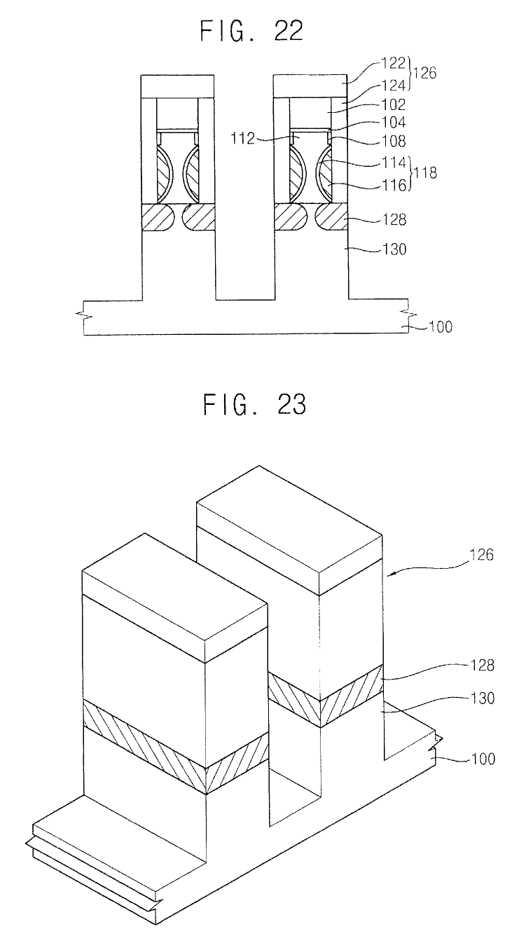

Referring to FIGS. 22 and 23, the substrate 100 is etched using the sacrificial layer patterns 126 as etching masks by an anisotropic process to form preliminary fin active patterns 130 and preliminary bit lines 128. The preliminary bit lines 128 may be electrically insulated from each other.

Each of the preliminary fin active patterns 130 may have a level sidewall. A cross-sectional area (and/or a width) of an upper portion of the preliminary fin active pattern 130 may be substantially the same as the cross-sectional area (and/or the width) of a lower portion of the preliminary fin active patterns 130.

The preliminary bit lines 128 are on surfaces of the preliminary fin active patterns 130. The preliminary bit lines 128 may extend in substantially the same direction as the preliminary fin active patterns 130 extend.

Referring to FIGS. 4 and 5, the preliminary fin active patterns 130 are etched using the sacrificial layer patterns 126 as etching masks to form fin active patterns 134 and bit lines 132. In some example embodiments, the etching process may include an isotropic etching process.

Each of the fin active patterns 134 may include a central portion and a peripheral portion. The central portion of the fin active patterns 134 may have a cross-sectional area (and/or a width) that is substantially smaller than the cross-sectional area (and/or the width) of the peripheral portion. In example embodiments, each fin active pattern 134 may have curved sidewalls.

The bit lines 132 are on the fin active patterns 134. A distance between adjacent bit lines 132 may be increased because the central portions of the fin active patterns 134 may have cross-sectional areas (and/or widths) that are substantially smaller than the cross-sectional areas (and/or the widths) of the peripheral portions of the fin active patterns 134. Mutual interference between adjacent the bit lines 132 and/or a parasitic capacitance in the array of the cells in the semiconductor device may be, reduced.

After forming the fin active patterns 134 and the bit lines 132, the sacrificial layer patterns 126 may be removed from the pillar active patterns 112.

In example embodiments of the present invention, the masks 102 may be removed from the pillar active patterns 112 to expose the pillar active patterns 112. Impurity regions (not illustrated) may be formed in the upper portions of the pillar active patterns 112. The impurity regions and the bit lines 132 may serve as source/drain regions.

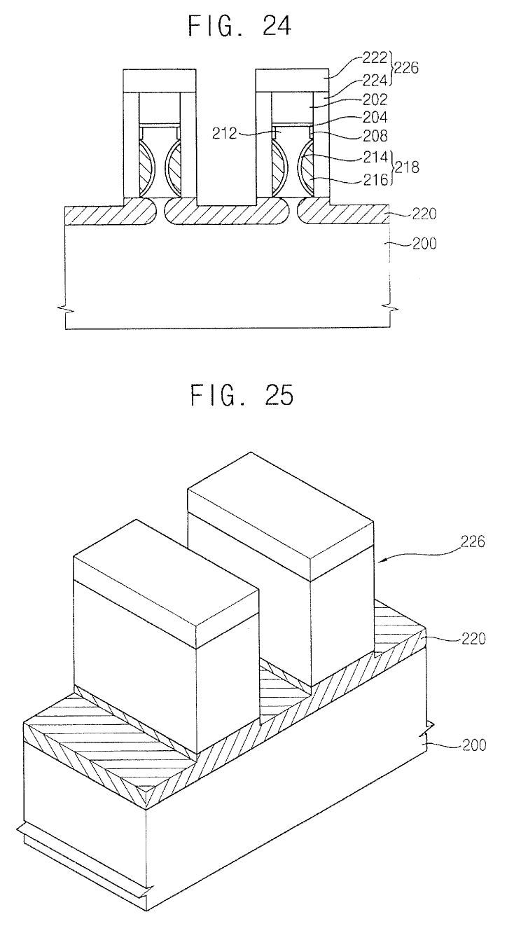

FIGS. 24 to 31 are views illustrating methods of manufacturing semiconductor devices in accordance with further embodiments of the present invention. FIGS. 24, 26, 28 and 30 are cross-sectional views, while FIGS. 25, 27, 29 and 31 are perspective views.

Referring to FIGS. 24 and 25, masks 202, pillar active patterns 212 and gates 218 surrounding lower and/or central portions of the pillar active patterns 212 are formed on a substrate 200. First impurity regions 220 are formed in the substrate 200 exposed by the pillar active patterns 212. Sacrificial layer patterns 226 are formed on the masks 202 and sidewalls of the pillar active patterns 212. In FIGS. 24 and 25, reference numerals of “204”, “208”, “214”, “216”, “222” and “224” indicate pad oxide patterns, first etch stop patterns, gate isolation layer patterns, gate electrodes, first sacrificial layer patterns and second sacrificial layer patterns, respectively.

Detailed descriptions of the method of forming the pillar active patterns 212, the gates 218, the first impurity regions 220 and the sacrificial layer patterns 226 will be omitted because processes for forming these elements are substantially the same or substantially similar to those described above with reference to FIGS. 8 to 21.

The first impurity regions 220 are partially etched using the sacrificial layer patterns 226 as etching masks. The first impurity regions 220 may be electrically connected to each other.

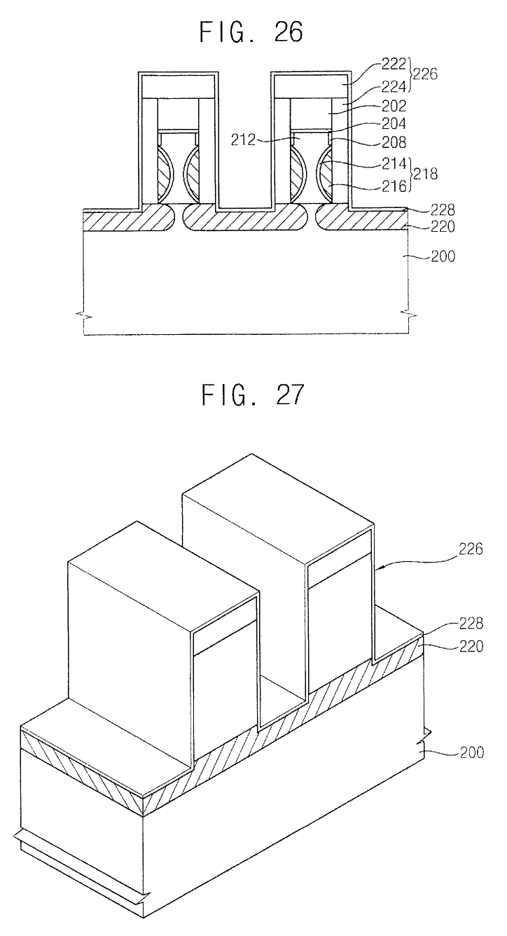

Referring to FIGS. 26 and 27, a second etch stop layer 228 is conformally formed on the sacrificial layer patterns 226 and the etched first impurity regions 220. The second etch stop layer 228 may be formed using a material that has etch selectivity with respect to the substrate 200. For example, the second etch stop layer 228 may be formed using an oxide such as middle temperature oxide (MTO).

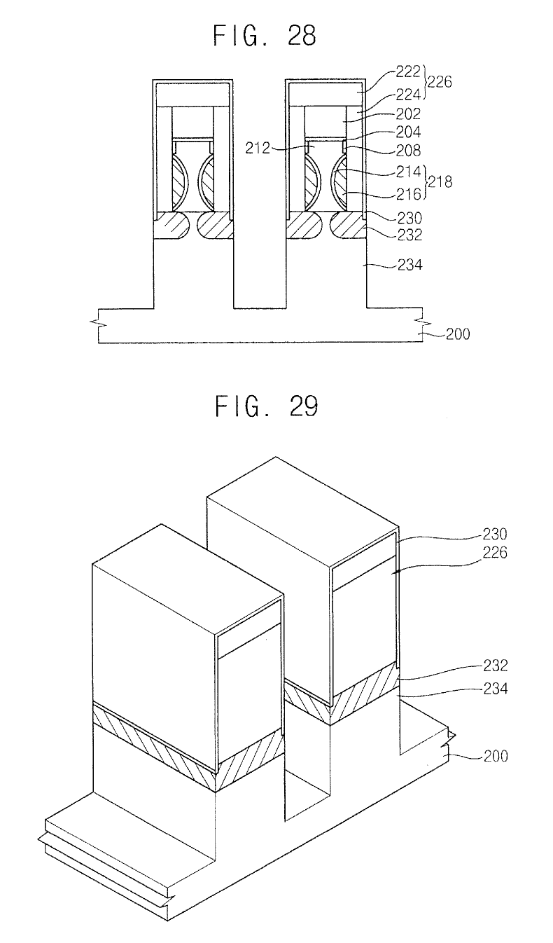

Referring to FIGS. 28 and 29, the second etch stop layer 228 is partially etched by an etching process to form second etch stop layer patterns 230 on sidewalls of the sacrificial layer patterns 226. In some embodiments, the etching process may include an isotropic etching process.

The substrate 200 is etched using the second etch stop layer patterns 230 and the sacrificial layer patterns 226 as etching masks to form preliminary fin active patterns 234 and preliminary bit lines 232.

Each of the preliminary fin active patterns 234 may have a level sidewall. Preliminary bit lines 232 may be formed using the etching process to electrically isolate the first impurity regions 220 from each other. The preliminary bit lines 232 may be formed on the preliminary fin active patterns 234. Each of the preliminary bit lines 232 may extend along a second direction.

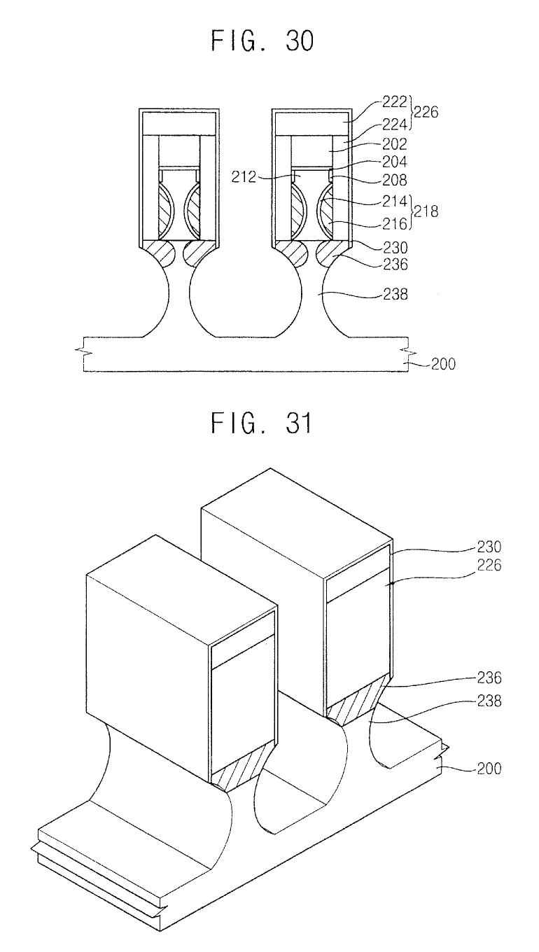

Referring to FIGS. 30 and 31, the preliminary fin active patterns 234 are etched using the second etch stop layer patterns 230 and the sacrificial layer patterns 226 as etching masks to form fin active patterns 238 and bit lines 236. In some example embodiments, the etching process may include an isotropic etching process.

Each of the fin active patterns 238 may include an upper portion and a lower portion. The upper portion of the fin active pattern 238 may have a level sidewall. A central portion of the fin active pattern 238 may have a cross-sectional area (and/or a width) that is substantially smaller than the cross-sectional area (and/or the width) of a peripheral portion of the fin active pattern 238. In some embodiments, the lower portion of the fin active pattern 238 may have a curved sidewall.

In the isotropic etching process, the lower portion of the fin active pattern 238 may be partially etched and the upper portion of the fin active pattern 238 may not be etched because the etch stop layer patterns 230 may protect the upper portion during the etching process. The fin active patterns 238 may have curved sidewalls.

The bit lines 236 are formed on the fin active patterns 238. In example embodiments, each of the bit lines 236 may extend from the upper portion of the fin active pattern 238 into the lower portion of the fin active pattern 238.

In some embodiments, the distance between a lower portion of a first bit line 236 and a lower portion of an adjacent bit line 236 may be increased. Therefore, mutual interference between adjacent bit lines 236 and/or a parasitic capacitance in the array of the cells in the semiconductor device may be reduced.

Additionally, the bit line 236 may have a substantially lower resistance because the bit line 236 may be formed on the upper portion of the pillar active pattern 212 having the level sidewall.

Referring now to FIGS. 6 and 7, the second etch stop layer patterns 230 are removed from the pillar active patterns 212.

After removing the second etch stop layer patterns 230, impurities may be implanted into the upper portions of the pillar active patterns 212 to form impurity regions.

According to example embodiments of the present invention, the distance between adjacent bit lines may be increased so that the mutual interference between adjacent bit lines and/or the parasitic capacitance in the array of the memory cells in the semiconductor device may be reduced.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A semiconductor device comprising:
a first active pattern on a substrate, wherein a width of a transverse cross-section of the first active pattern is non-uniform;
a second active pattern having a pillar structure on the first active pattern, the second active pattern including a channel; and
a gate surrounding the second active pattern.

2. The semiconductor device of claim 1, wherein the first active pattern includes a curved sidewall.

3. The semiconductor device of claim 2, wherein a width of an upper portion of a transverse cross-section of the first active pattern is larger than a minimum width of a lower portion of the transverse cross-section of the first active pattern.

4. The semiconductor device of claim 3, wherein the channel is oriented substantially perpendicular to a surface of the substrate from which the first active pattern protrudes.

5. The semiconductor device of claim 4, further comprising an impurity region at the upper portion of the first active pattern.

6. The semiconductor device of claim 1, wherein the first active pattern includes an upper portion and a lower portion, and wherein the upper portion of the first active pattern has a planar sidewall.

7. The semiconductor device of claim 6, wherein the first active pattern includes an impurity region that extends from the upper portion of the first active pattern into an upper region of the lower portion of the first active pattern.

8. A method of manufacturing a semiconductor device, comprising:
forming a first active pattern having a mesa structure with a transverse cross-section of non-uniform width on a substrate;
forming a second active pattern that has a pillar structure on the first active pattern; and
forming a gate surrounding a sidewall of the second active pattern that defines a channel through the second active pattern.

9. The method of claim 8, wherein forming the first active pattern comprises:
patterning the substrate to form a preliminary first active pattern; and
isotropically etching the preliminary first active pattern to form the first active pattern,
wherein the first active pattern has a curved sidewall.

10. The method of claim 9, wherein a width of an upper portion of a transverse cross-section of the first active pattern is larger than a minimum width of a lower portion of a transverse cross-section of the first active pattern.

11. The method of claim 10, wherein the channel is oriented substantially perpendicular to a surface of the substrate from which the first active pattern protrudes.

12. The method of claim 11, further comprising forming an impurity region at the upper portion of the first active pattern.

13. The method of claim 8, wherein forming the first active pattern comprises:
patterning the substrate to form a first preliminary first active pattern;
forming a sacrificial layer pattern on an upper portion and a sidewall of the first preliminary first active pattern;
etching the substrate using the sacrificial layer pattern as an etching mask to form a second preliminary first active pattern; and
etching a sidewall of the second preliminary first active pattern using the sacrificial layer pattern as an etching mask to form the first active pattern, wherein the upper portion of the first active pattern has a level sidewall and the lower portion of the first active pattern has a curved sidewall.

14. The method of claim 13, further comprising:
forming an impurity region in the first active pattern that extends from the upper portion of the first active pattern into an upper region of the lower portion of the first active pattern.

15. A semiconductor device comprising:
fin active patterns including upper portions and lower portions, the fin active patterns extending along a predetermined direction and being parallel to each other, wherein a transverse cross-section of each of the fin active patterns has a non-uniform width;
bit lines in the fin active patterns;
pillar active patterns on the fin active patterns, the pillar active patterns being separated from each other by a predetermined distance; and
gates surrounding the pillar active patterns to form a channel through each of the pillar active patterns, wherein each channel is oriented substantially perpendicular to a major axis of its respective pillar active pattern.

16. The semiconductor device of claim 15, wherein each of the fin active patterns includes a curved sidewall.

17. The semiconductor device of claim 15, wherein the upper portion of each of the fin active patterns has a level sidewall.

18. The semiconductor device of claim 17, wherein the bit lines extend from the upper portion of the first active pattern into an upper region of the lower portion of the first active pattern.

19. The semiconductor device of claim 15, further comprising impurity regions formed at upper portions of the pillar active patterns.

20. The semiconductor device of claim 15, wherein the bit lines are formed in at least the upper portions of the fin active patterns, and wherein at least part of a sidewall of each bit line that faces an adjacent bit line is curved.

21. A method of manufacturing a semiconductor device, comprising:
patterning a substrate to form pillar active patterns;
forming impurity regions at portions of the substrate adjacent to the pillar active patterns;
forming gates on sidewalls of the pillar active patterns, wherein each gate surrounds the sidewall of a respective one of the pillar active patterns;
forming masks on the pillar active patterns and the gates, wherein the masks extend along a predetermined direction and are parallel to each other; and
etching the substrate using the masks to form bit lines and fin active patterns, wherein each of the bit lines has a non-planar sidewall.

22. The method of claim 21, wherein forming the bit lines and the fin active patterns comprises:
anisotropically etching the substrate using the masks to form preliminary fin active patterns and preliminary bit lines; and
isotropically etching the preliminary fin active patterns and the preliminary bit lines to form the fin active patterns and the bit lines, wherein each fin active pattern has a curved sidewall.

23. The method of claim 21, wherein forming the bit lines and the fin active patterns comprises:
etching the substrate to form first preliminary fin active patterns using the masks;
forming sacrificial layer patterns on upper faces and sidewalls of each first preliminary fin active pattern;
etching the substrate using the sacrificial layer patterns and the masks to form second preliminary fin active patterns; and
etching sidewalls of the second preliminary fin active patterns using the sacrificial layer patterns to form the fin active patterns, wherein upper portions of the fin active patterns have level sidewalls and lower portions of the fin active patterns have curved sidewalls.

24. The method of claim 21, further comprising forming impurity regions at the pillar active patterns, wherein each impurity regions extends from an upper portion of a respective one of the fin active patterns into an upper region of a lower portion of the respective one of the fin active patterns.

25. A semiconductor device, comprising:
a first active pattern extending from an upper surface of a semiconductor substrate;
a first impurity-doped region in an upper portion of the fin active pattern, the first impurity-doped region having a sidewall that is at least partly curved; and
a second active pattern on an upper surface of the first active pattern, the second active pattern including a gate pattern encircling at least one side surface of the second active pattern, a second impurity-doped region in an upper portion of the second active pattern, and a channel extending between the first impurity-doped region and the second impurity-doped region such that the channel is oriented substantially perpendicular to the upper surface of the semiconductor substrate.
